(19) United States
(12) Patent Application Publication
(10) Pub. No.: US 2014/0146502 A1
(43) Pub. Date: May 29, 2014

(54) CIRCUIT BOARD MOUNTING APPARATUS

(71) Applicant: HON HAI PRECISION INDUSTRY CO., LTD., New Taipei (TW)

(72) Inventor: ZHENG-HENG SUN, New Taipei (TW)

(73) Assignee: HON HAI PRECISION INDUSTRY CO., LTD., New Taipei (TW)

(21) Appl. No.: 13/864,253

(22) Filed: Apr. 17, 2013

(30) Foreign Application Priority Data
Nov. 28, 2012 (CN) 201210494024.8

(51) Int. Cl. H05K 7/14

(52) U.S. Cl. CPC H05K 7/1417
USPC 361/767

(57) ABSTRACT

A circuit board mounting apparatus includes a chassis, a circuit board defining two recesses in a front side, two fixing members engaged in the recesses, and two fasteners. The chassis includes a side plate defining two through holes. Each recess is bounded by two sidewalls. A latching slot is defined in each sidewall. A fixing hole is defined in a front side of each fixing member. Two resilient arms are formed at opposite sides of each fixing member, and slantingly extend into the corresponding fixing hole. A projection protrudes from an outer surface of each resilient arm. The fasteners extend through the through holes of the side plate and engage in the fixing holes of the fixing members. The resilient arms are deformed outward by the fasteners, to allow the projections to engage in the corresponding latching slots. Therefore, the circuit board is perpendicularly fixed to the side plate.

### BACKGROUND

1. Technical Field

The present disclosure relates to a mounting apparatus for fixing a circuit board.

2. Description of Related Art

Circuit boards are often mounted in chassis by screws which extend through a circuit board and engage in a bottom wall of the chassis. However, this fixing means is time consuming, and will occupy a large part of the circuit board.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an embodiment of a circuit board mounting apparatus; the mounting apparatus includes a circuit board and two fixing members.

FIG. 2 is a partially cross-sectional view of FIG. 1, taken along the line II-II.

FIG. 3 is an exploded, isometric view of FIG. 1.

FIG. 4 is an enlarged view of the circuit board of FIG. 1.

FIG. 5 is an enlarged view of one of the fixing members of FIG. 3.

FIG. 6 is a partially cross-sectional view of FIG. 3, taken along the line VI-VI.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

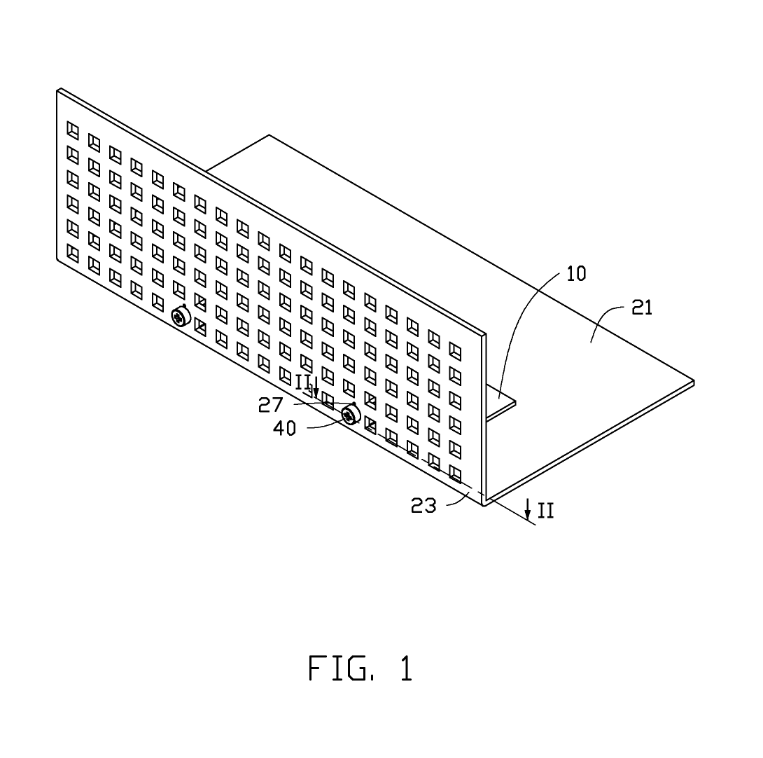

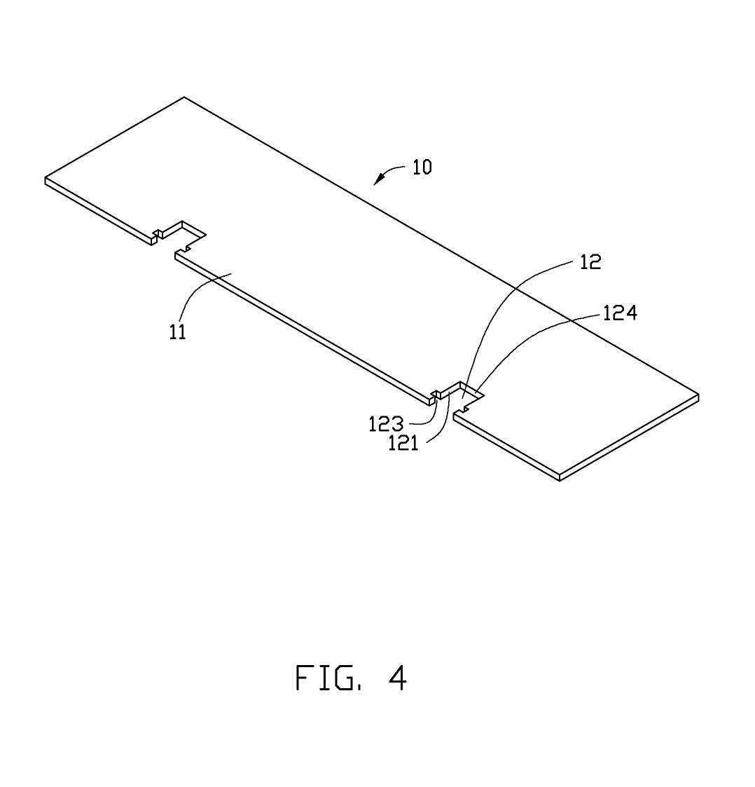

Referring to FIGS. 1, 3, and 4, an exemplary embodiment of a circuit board mounting apparatus includes a circuit board 10, a chassis 20, two fixing members 30, and two fasteners 40. In this embodiment, the fasteners 40 are screws.

The circuit board 10 defines two recesses 12 in a front side 11. Each recess 12 is bounded by two opposite sidewalls 121 and an end wall 124 connected between rear ends of the sidewalls 121. A first end of the recess 12 opposite to the end wall 124 is open. A latching slot 123 is defined in each sidewall 121, communicating with the recess 12.

The chassis 20 includes a bottom wall 21 and a side plate 23 perpendicularly connected to a front side of the bottom wall 21. The side plate 23 defines two through holes 25 adjacent to the bottom wall 21. Two positioning holes 27 are defined in the side plate 23, respectively above and below each through hole 25.

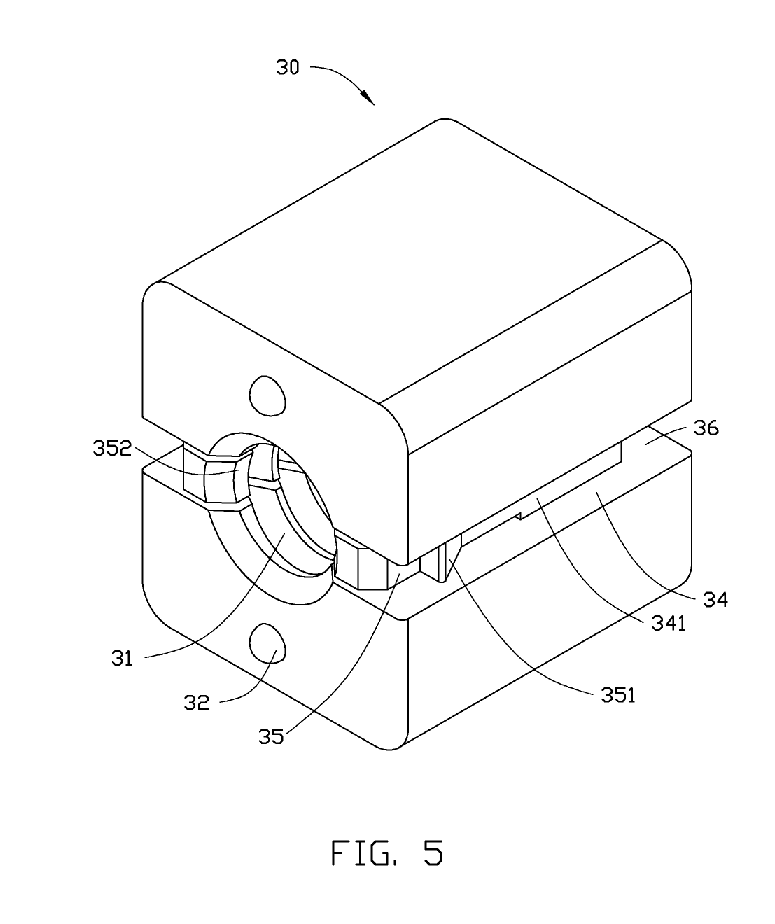

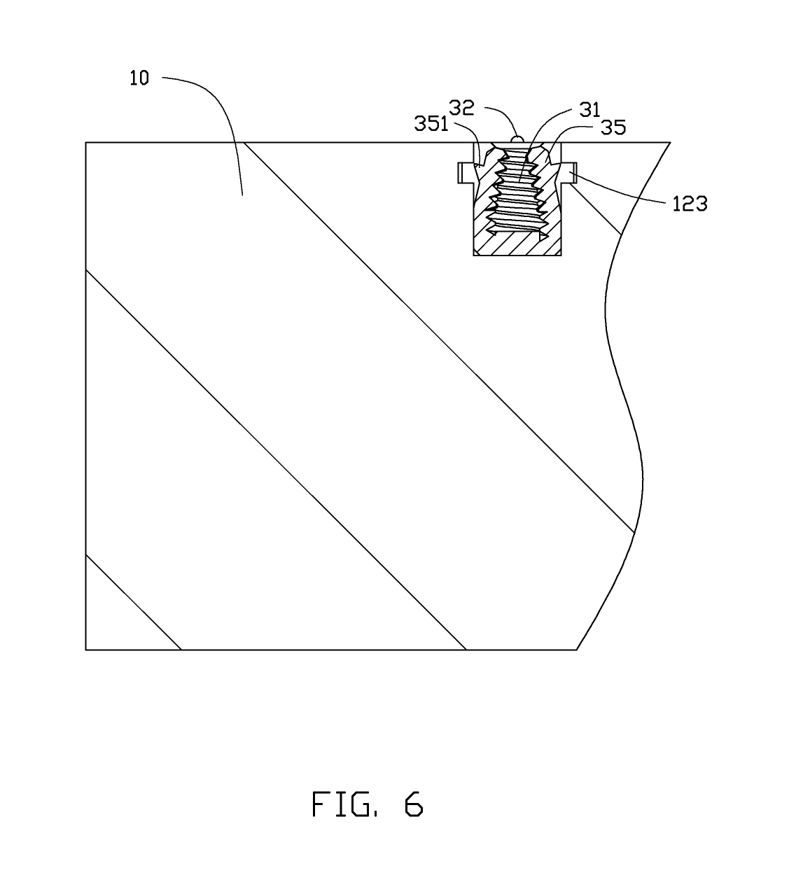

Referring to FIG. 5, each fixing member 30 is rectangular and defines a fixing hole 31 in a center of a front side. Two pins 32 protrude from the front side of the fixing member 30, respectively above and below the fixing hole 31. Two first slide slots 34 are defined in opposite sides of the fixing member 30 and extend through the front side and a rear side of the fixing member 30. A spaced wall 341 is formed between rear ends of the fixing hole 31 and each first slide slot 34. A resilient arm 35 extends forward from each spaced wall 341. The resilient arm 35 is slantingly extended into the fixing hole 31 (shown in FIG. 6). A projection 351 protrudes from an outer surface of each resilient arm 35. A second slide slot 36 is defined in the rear side of the fixing member 30 and perpendicularly communicates with the first slide slots 34. In this embodiment, the fixing hole 31 is a threaded hole. The resilient arms 35 form threaded portions 352 in inner surfaces. The threaded portions 352 are consistent with threaded portions of an inner surface bounding the fixing hole 31. In another embodiment, the threaded portions 352 can be omitted.

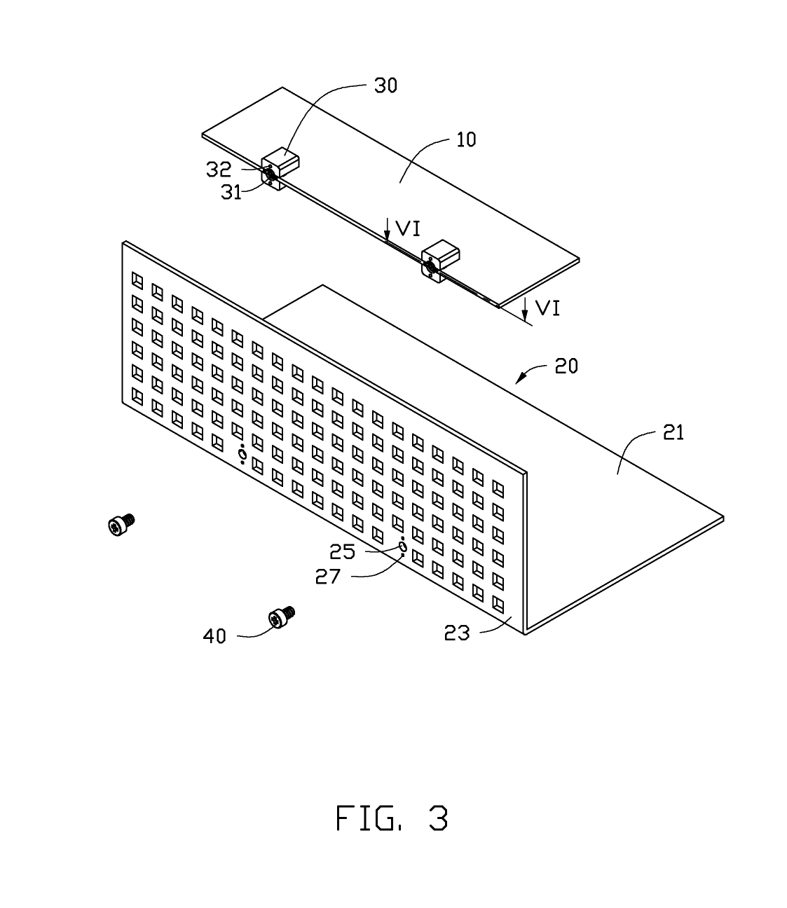

Referring to FIGS. 3 to 6, in assembly, each fixing member 30 is engaged in one of the recesses 12. The sidewalls 121 bounding the recess 12 are engaged in the corresponding first slots 34, and the end wall 124 bounding the recess 12 is engaged in the corresponding second slot 36. At this time, the resilient arms 35 are still slantingly extended into the corresponding fixing hole 31, with the projections 351 aligning with the corresponding latching slots 123.

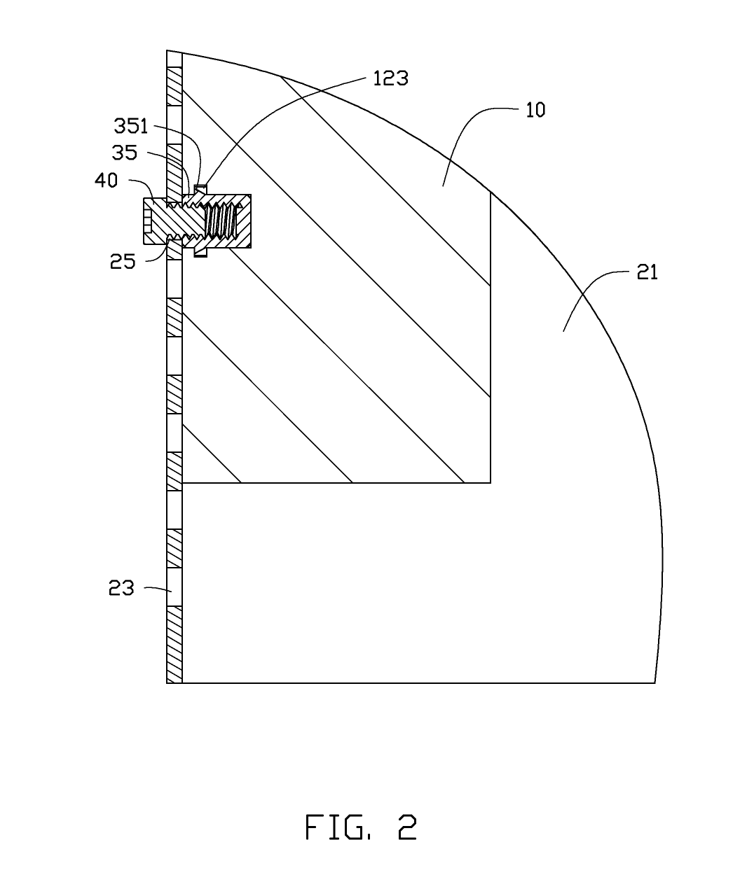

Referring to FIGS. 1 and 2, the circuit board 10 is perpendicularly mounted to the side plate 23, the pins 32 are engaged in the corresponding positioning holes 27, until the front sides of the fixing members 30 abut against a rear side of the side plate 23. The fixing members 30 are supported on the bottom wall 21. The fasteners 40 extend through the through holes 25 and are engaged in the fixing holes 31. The resilient arms 35 are deformed outward by the fasteners 40, and the projections 351 are engaged in the corresponding latching slots 123, thereby fixing the circuit board 10 in the chassis 20 and above the bottom wall 21.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting apparatus, comprising:
a chassis comprising a side plate defining two through holes;
a circuit board defining two recesses in a front side, each recess bounded by two opposite sidewalls, each sidewall defining a latching slot;
two fixing members engaged in the recesses, each fixing member defining a fixing hole in a front side, two resilient arms connected to opposite sides of each fixing member and slantingly extending into the corresponding fixing hole, a projection protruding from an outer surface of each resilient arm; and
two fasteners;
wherein when the two fasteners extend through the through holes and are engaged in the corresponding fixing holes, the resilient arms are deformed by the fasteners and moved outward to allow the projections to engage in the corresponding latching slots.

2. The mounting apparatus of claim 1, wherein each fixing member defines two first slide slots in opposite sides, the first slide slots extending through the front side and a rear side of the fixing member, a spaced wall is formed between the fixing hole and each first slide slot, each resilient arm slantingly extends forward from the corresponding spaced wall, the sidewalls of each recess are engaged in the corresponding first slide slots.

3. The mounting apparatus of claim 2, wherein each recess is further bounded by an end wall connected between rear ends of the corresponding sidewalls, each fixing member further defines a second slide slot in the rear side, the second slide slot perpendicularly communicates with the corresponding first slide slots to receive the end wall of the corresponding recess.

4. The mounting apparatus of claim 1, wherein the side plate further defines two positioning holes, a pin protrudes from the front side of each fixing member to be engaged in a corresponding one of the positioning holes.

5. The mounting apparatus of claim 1, wherein each fixing hole is a threaded hole, each fastener is a screw.

6. The mounting apparatus of claim 2, wherein each fixing hole is a threaded hole, each fastener is a screw.

7. The mounting apparatus of claim 6, wherein each resilient arm forms a threaded portion in an inner surface, the threaded portion is consistent with threaded portions of an inner surface bounding the fixing hole.
